(19) United States
(12) Patent Application Publication
(10) Pub. No.: US 2009/0009204 A1
(43) Pub. Date: Jan. 8, 2009

(54) Test socket

(75) Inventors: Sang-Sik Lee, Suwon-si (KR); Bo-Woo Kim, Suwon-si (KR); Ho-Jeong Choi, Yongin-si (KR)

Correspondence Address: MILLS & ONELLO LLP, ELEVEN BEACON STREET, SUITE 605, BOSTON, MA, 02108, US

(73) Assignee: Samsung Electronics Co. Ltd., Suwon-si (KR)

(21) Appl. No.: 12/214,932

(22) Filed: Jun. 24, 2008

(30) Foreign Application Priority Data
Jul. 5, 2007 (KR) 10-2007-0067341

(51) Int. Cl. G01R 31/02

(52) U.S. Cl. 324/760

(57) ABSTRACT

A test socket in accordance with one aspect of the present invention includes a socket body, a thermoelectric element and a heat transfer member. The socket body receives an object. The thermoelectric element is arranged in the socket body to emit heat and absorb heat in accordance with current directions. The heat transfer member is arranged between the object and the thermoelectric element to transfer a heat generated from the object to the thermoelectric element. Thus, the object may be directly provided with a desired test temperature using the thermoelectric element so that the desired test temperature may be set rapidly and accurately. Further, the heat transfer member interposed between the object and the thermoelectric element may quickly dissipate the heat in the object.

### CROSS-REFERENCE TO RELATED APPLICATIONS

This application claims priority under 35 U.S.C. § 119 to Korean Patent Application No. 10-2007-0067341 filed on Jul. 5, 2007 in the Korean Intellectual Property Office (KIPO), the contents of which are herein incorporated by reference in their entirety.

### BACKGROUND OF THE INVENTION

1. Field of the Invention

The present invention relates to the field of test sockets. More particularly, example embodiments of the present invention relate to a test socket for testing electrical characteristics of a semiconductor package.

2. Description of the Related Art

Generally, various semiconductor processes may be performed on a wafer to form a plurality of semiconductor chips. To mount the semiconductor chips on a printed circuit board (PCB), a packaging process may be performed on the wafer to form semiconductor packages.

Electrical characteristics of the semiconductor package, which may be manufactured by the above-mentioned processes, may be tested. According to a conventional test method, the semiconductor package may be loaded into a test chamber. The semiconductor package may be held in a test socket. The semiconductor package in the test socket may electrically make contact with a test board. A test current may be supplied to the semiconductor package through the test board to test the electrical characteristics of the semiconductor package.

Here, in order to test the electrical characteristics of the semiconductor package under various temperatures, the test process may be carried out under the various temperatures. Thus, a separate temperature controller, which may be located outside of the test chamber, may provide hot or cold air to the test chamber to set the various temperatures in the test chamber. However, according to the conventional method, it may take a very long time to heat or cool the test chamber. Therefore, the test chamber reaches a desired test temperature after a relatively long time of heating or cooling.

Further, the semiconductor package may be indirectly provided with a desired test temperature using the air provided from outside of the test chamber. Thus, an inner temperature of the test chamber may have a large deviation. As a result, the test process with respect to the semiconductor package is not necessarily performed under a desired accurate test temperature, so that the conventional test process may have a low reliability.

### SUMMARY OF THE INVENTION

Some embodiments of the present invention provide a test socket that is capable of rapidly and accurately setting a desired test temperature.

A test socket in accordance with one aspect of the present invention includes a socket body, a thermoelectric element and a heat transfer member. The socket body receives an object. The thermoelectric element is arranged in the socket body to emit heat and absorb heat in accordance with current directions. The heat transfer member is arranged between the object and the thermoelectric element to transfer a heat generated from the object to the thermoelectric element.

The socket body may include a base and a lid. The object may be fixed to the base. The lid may be rotatably connected to the base to cover the base. Further, the thermoelectric element and the heat transfer member may be held by the lid.

The socket body may further include a latch rotatably connected to the lid to detachably fix the lid to the base.

The socket body may further include a locking spring configured to resiliently bias the latch toward the base.

The latch may have a holding protrusion selectively held in a holding groove formed at the base.

The lid may include a housing for movably receiving the heat transfer member.

The test socket may further include a contact spring to resiliently bias the heat transfer member toward the object to ensure an electrical contact between the heat transfer member and the object.

The test socket may further include a heat spreader contacting the thermoelectric element to dissipate the heat from the thermoelectric element.

Further, the heat spreader may have a plurality of protrusions that enlarge a heat radiation area of the heat spreader.

The test socket may further include a fan for sucking the heat of the thermoelectric element.

The object may comprise a semiconductor package.

The thermoelectric element may comprise: first and second heat-emitting plates configured to emit the heat; a heat-absorbing plate electrically connected to the first and second heat-emitting plates to absorb the heat; and N-type and P-type semiconductor devices interposed between the heat-absorbing plate and the first and second heat-emitting plates.

In accordance with another aspect of the present invention, provided is a test socket comprising: a base configured to hold an object; a lid rotatably connected to the base to cover the base; a latch rotatably connected to the lid to detachably fix the lid to the base; a locking spring configured to resiliently bias the latch toward the base; a thermoelectric element placed in the lid to emit heat and absorb heat by a current provided to the thermoelectric element; a heat transfer member arranged between the object and the thermoelectric element to transfer the heat in the object to the thermoelectric element; a heat spreader making contact with the thermoelectric element to dissipate the heat in the thermoelectric element; a contact spring installed at the heat spreader to resiliently bias the heat spreader, the thermoelectric element and the heat transfer member toward the object; and a fan arranged over the heat spreader to suck the heat in the heat spreader.

The latch may include a holding protrusion selectively inserted into a holding groove that is formed at the base.

The heat spreader may have a plurality of protrusions configured to enlarge a heat dissipation area of the heat spreader, and the contact spring may be wound on the holding protrusions.

In accordance with yet another aspect of the invention, provided is a test socket comprising: a socket body configured to receive a semiconductor package; a thermoelectric element placed in the socket body to emit heat and absorb heat by a current provided to the thermoelectric element; and a heat transfer member arranged between the semiconductor package and the thermoelectric element to transfer the heat in the semiconductor package to the thermoelectric element; a heat spreader making contact with the thermoelectric element to dissipate the heat in the thermoelectric element; and a fan arranged over the heat spreader to suck the heat in the heat spreader.

The heat spreader may have a plurality of protrusions configured to enlarge a heat dissipation area of the heat spreader.

The test socket may further comprise a contact spring configured to resiliently bias the heat spreader, the thermoelectric element and the heat transfer member toward the semiconductor package.

According to aspects of the present invention, the object may be directly provided with a desired test temperature using the thermoelectric element. Thus, the desired test temperature may be set rapidly and accurately. Further, the heat transfer member interposed between the object and the thermoelectric element may quickly dissipate the heat in the object.

### BRIEF DESCRIPTION OF THE DRAWINGS

The above and other features and advantages of the present invention will become readily apparent by reference to the following detailed description when considered in conjunction with the accompanying drawings, wherein:

FIG. 1 is a cross-sectional view illustrating an embodiment of a test socket in accordance with an aspect of the present invention;

FIG. 2 is a side view illustrating the test socket in FIG. 1;

FIG. 3 is a cross-sectional view illustrating the test socket in FIG. 1 in which a lid is opened;

FIG. 4 is a cross-sectional view illustrating a thermoelectric element of the test socket in FIG. 1; and

FIG. 5 is a cross-sectional view illustrating a process for testing semiconductor packages using the test sockets in FIG. 1 under various test temperatures.

### DESCRIPTION OF EXAMPLE EMBODIMENTS

Aspects of the present invention are described more fully hereinafter with reference to the accompanying drawings, in which example embodiments in accordance with the present invention are shown. The present invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

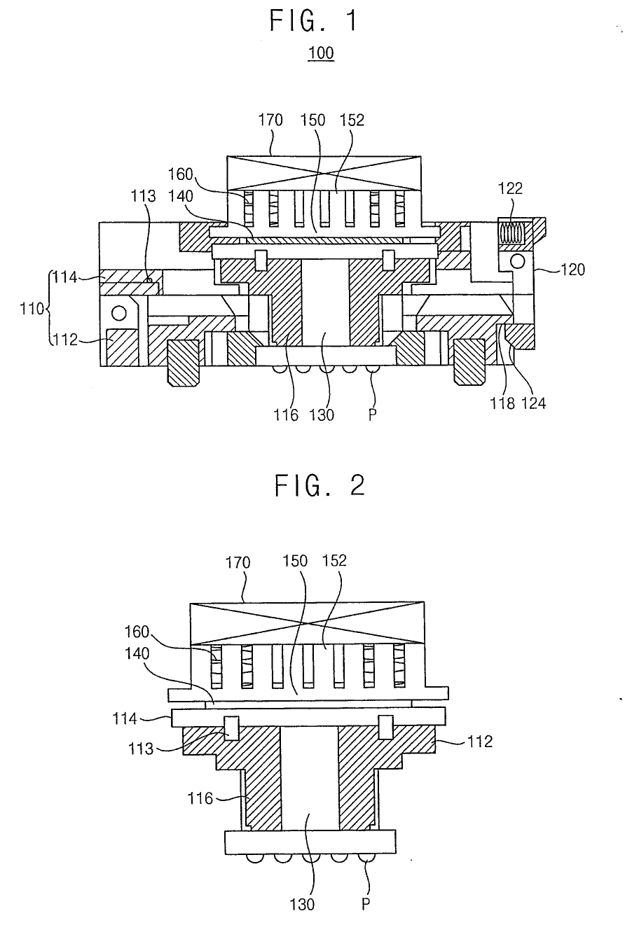

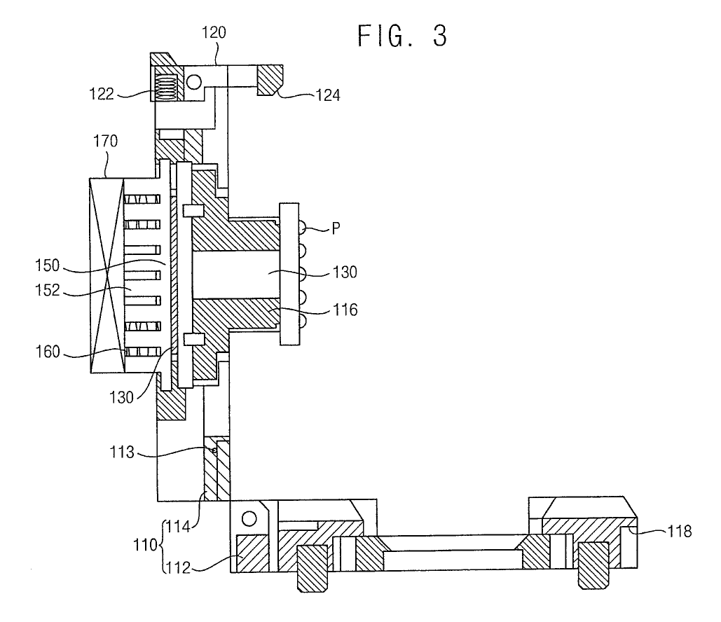

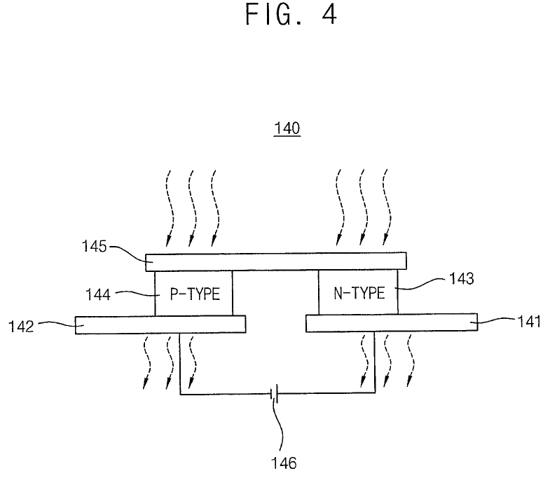

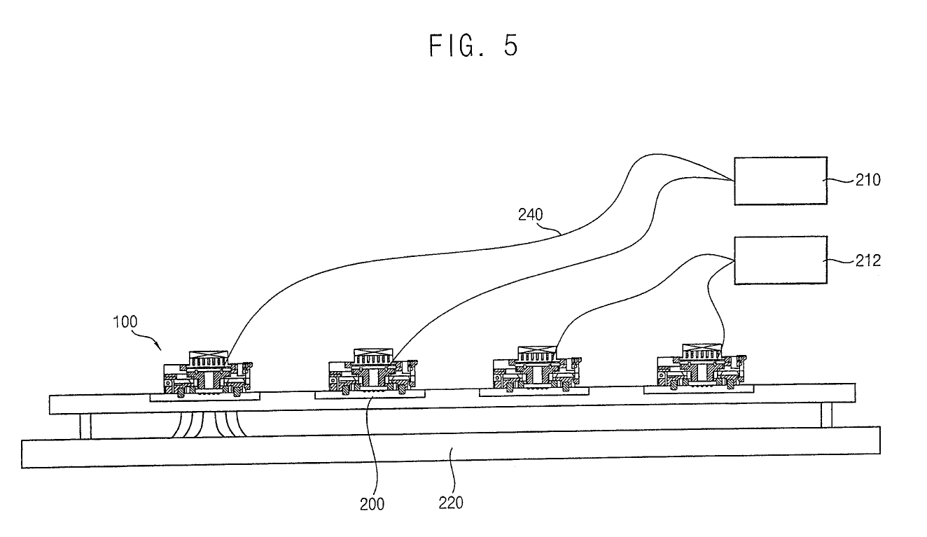

FIG. 1 is a cross-sectional view illustrating an example embodiment of a test socket in accordance with an aspect of the present invention, FIG. 2 is a side view illustrating the test socket in FIG. 1, FIG. 3 is a cross-sectional view illustrating the test socket in FIG. 1 in which a lid is opened, FIG. 4 is a cross-sectional view illustrating a thermoelectric element of the test socket in FIG. 1, and FIG. 5 is a cross-sectional view illustrating a process for testing semiconductor packages using the test sockets in FIG. 1 under various test temperatures.

Referring to FIGS. 1 and 2, a test socket 100 of this example embodiment includes a socket body 110, a heat transfer member 130, a thermoelectric element 140, a heat spreader 150, a contact spring 160, and a fan 170.

The socket body 110 includes a base 112 and a lid 114. The base 112 may receive an object whose electrical characteristics are to be tested, such as a semiconductor package P. The base 112 is placed on a test board 200 (see FIG. 5) for supplying a test current to the semiconductor package P. That is, the test current may be supplied to the semiconductor package P from the test board 200 to test the electrical characteristics of the semiconductor package P.

The lid 114 covers the base 112. In this example embodiment, a left portion of the lid 114 may be rotatably connected to the base 112 via a hinge pin 113. Thus, as shown in FIG. 1, the lid 114 may rotate in a clockwise direction and cover the base 112. The lid 114 may also rotate in a counterclockwise direction to open the base 112.

A latch 120 is rotatably connected to a right portion of the lid 114. The latch 120 detachably secures the lid 114 to the base 112. A holding protrusion 124 is formed at an end of the latch 120. The holding protrusion 124 is inserted into a holding groove 118, which is formed at a right face of the base 112. That is, the holding protrusion 124 is held in the holding groove 118. Further, a locking spring 118 is wound on a hinged portion of the latch 120 to resiliently support the latch 120 in the clockwise direction. Thus, since the holding protrusion 124 in the holding groove 118 may be resiliently supported by the locking spring 122 toward an inner direction of the holding groove 118, the holding protrusion 124 is not detached from the holding groove 118 under a condition that an external force is not applied to the latch 120. As a result, the lid 114 fixed to the base 112 may be maintained by the latch 120.

A housing 116 is installed at a central portion of the lid 114. The housing 116 has a hole vertically formed through the housing 116. Further, an upper surface of the semiconductor package P may be supported by a lower face of the housing 116.

The heat transfer member 130 is movably inserted into the hole of the housing 116. The heat transfer member 130 has a lower end making contact with the upper surface of the semiconductor package P. Thus, a heat generated from the semiconductor package P in the test process may be rapidly transferred to the heat transfer member 130. In this example embodiment, the heat transfer member 130 may include a material having high heat conductivity such as gold, copper, aluminum, etc.

The thermoelectric element 140 is located on the heat transfer member 130. The thermoelectric element 140 may serve to test the semiconductor package P under various temperatures. The thermoelectric element 140 makes contact with an upper surface of the heat transfer member 130. Therefore, the heat in the semiconductor package P may be quickly transferred to the thermoelectric element through the heat transfer member 130. The thermoelectric element 140 may be capable of emitting heat and absorbing heat by the current provided to the thermoelectric element 140 in accordance with Peltier effect.

Referring to FIG. 4, the thermoelectric element 140 includes first and second heat-emitting plates 141 and 142, a heat-absorbing plate 145 opposite to the first and second heat-emitting plates 141 and 142, and N type and P type semiconductor devices 143 and 144 interposed between the heat-absorbing plate 145 and the first and second heat-emitting plates 141 and 142. A power supply 146 is electrically connected to the first and second heat-emitting plates 141 and 142.

A current is provided to the first heat-emitting plate 141 from the power supply 146. The current flows to the second heat-emitting plate 142 through the N type semiconductor device 143, the heat-absorbing plate 145 and the P type semiconductor device 144. Thus, the first and second heat-emitting plates 141 and 142 emit heat. The heat-absorbing plate 145 absorbs heat. In contrast, when a current is provided to the second heat-emitting plate 142 from the power supply 146, the current flows to the first heat-emitting plate 141 through the P type semiconductor device 144, the heat-absorbing plate 145 and the N type semiconductor device 143. Thus, the first and second heat-emitting plates 141 and 142 absorb heat. The heat-absorbing plate 145 emits heat. This is due to the well-known Peltier effect.

The Peltier effect may be explained as a principle that an ideal gas is cooled by a constant entropy expansion. When an electron moves from a semiconductor having a high electron concentration to a semiconductor having a low electron concentration, an electron gas expands and then works with respect to a potential barrier between two plates having a substantially similar chemical potential, thereby electrically cooling an object.

Referring again to FIGS. 1 and 2, the heat spreader 150 is installed on an upper surface of the thermoelectric element 140. Thus, the heat spreader 150 makes contact with the upper surface of the thermoelectric element 140 to rapidly dissipate the heat transferred to the thermoelectric element 140 from the semiconductor package P. Additionally, since heat dissipation effect is proportional to a heat dissipation area, the heat spreader 150 may have a plurality of protrusions 152 to enlarge the heat dissipation area. In this example embodiment, the protrusions 152 may be vertically formed from an upper surface of the heat spreader 150.

The contact springs 160 are wound on outer faces of the protrusions 152, respectively. The contact springs 160 resiliently bias the heat spreader 150, the thermoelectric element 140 and the heat transfer member 130 toward a downward direction to ensure a contact between the heat transfer member 130 and the semiconductor package P.

The fan 170 is arranged on the heat spreader 150. The fan 170 sucks the heat transferred from the semiconductor package P to the heat spreader 150 to more rapidly dissipate the heat to the outside. The fan 170 may be connected to the contact springs 160. Thus, the contact springs 160 may resiliently support the fan 170.

Referring to FIGS. 1 and 3, the semiconductor package P is secured on the lower surface of the housing 116. When the lid 114 is rotated clockwise with respect to the hinge pin 113, the lid 114 covers the base 112. Here, the holding protrusion 124 is inserted into the holding groove 118. Further, since the locking spring 122 resiliently biases the holding protrusion 124 toward the inner space of the holding groove 118, the holding protrusion 124 is not detached from the holding groove 118.

Referring to FIG. 5, a plurality of the semiconductor packages P may be tested using a plurality of the test sockets 100 under various test temperatures. The semiconductor packages P may make contact with upper surfaces of the test boards 200. The semiconductor packages P and the test boards 200 may be electrically coupled to each other. The test boards 200 may be positioned on table of a tester (not shown). The test sockets 100 may be selectively connected to a first power supply 210 for a high temperature and a second power supply 212 for a low temperature through cables 240. Thus, the semiconductor packages P in the test sockets 100 may be provided with different test temperatures. As a result, the electrical test process of the semiconductor packages P may be performed simultaneously under a high temperature and a low temperature. Accordingly, a test time may be remarkably decreased.

After the semiconductor packages P are tested, an upper portion of the latch 120 is rotated counterclockwise. The latch 120 compresses the locking spring 122. Thus, the holding protrusion 124 is detached from the holding groove 118. As a result, as shown in FIG, 3, the lid 114 is rotated counterclockwise to open the base 112. The semiconductor packages P are then unloaded from the lid 114.

Here, in this example embodiment, the object may include the semiconductor package. Alternatively, the test socket may be applied to other electronic devices as well as the semiconductor package. Some tests in accordance with the example embodiment were performed, as discussed below.

### Testing Temperature of Test Socket

1. Cooling Test

A first temperature sensor was attached to the semiconductor package. Further, a second temperature sensor was attached to the heat spreader. Nine voltages were applied to the thermoelectric element. Further, 12 voltages were applied to the fan. Temperatures of the semiconductor package and the heat spreader were measured six times at intervals of ten minutes.

The measured temperatures of the semiconductor package and the heat spreader using the first temperature sensor and the second temperature sensor are shown in a following table 1.

TABLE 1

| | Temperature of | |
|---|---|---|
| minute | semiconductor package | Temperature of heat spreader |
| 0 | 29.6° C. | 27.3° C. |
| 10 | −16.0° C. | 37.1° C. |
| 20 | −20.2° C. | 36.9° C. |
| 30 | −20.8° C. | 36.8° C. |
| 40 | −20.5° C. | 37.0° C. |
| 50 | −21.0° C. | 36.2° C. |
| 60 | −20.9° C. | 36.0° C. |

As shown in Table 1, an initial temperature of the semiconductor package is 29.6° C. and an initial temperature of the heat spreader is 27.3° C. Temperatures of the semiconductor package and the heat spreader measured after 20 minutes are −20.2° C. and 36.9° C., respectively. Temperatures of the semiconductor package and the heat spreader are still maintained after 60 minutes. Thus, it may be noted that a desired cooling temperature may be rapidly set using the test socket of the present invention. Further, it may be noted that the desired cooling temperature may be maintained continuously and constantly.

2. Heating Test

A first temperature sensor was attached to the semiconductor package. Further, a second temperature sensor was attached to the heat spreader. A polarity of the thermoelectric element in the cooling test was reversed. Nine voltages were applied to the thermoelectric element. Further, 12 voltages were applied to the fan. Temperatures of the semiconductor package and the heat spreader were measured after ten minutes.

The measured temperatures of the semiconductor package and the heat spreader using the first temperature sensor and the second temperature sensor are shown in a following table 2.

TABLE 2

| | Temperature of | |
|---|---|---|
| minute | semiconductor package | Temperature of heat spreader |
| 0 | 28.1° C. | 25.9° C. |
| 10 | 150.0° C. | 29.0° C. |

As shown in Table 2, an initial temperature of the semiconductor package is 28.1° C. and an initial temperature of the heat spreader is 25.9° C. Temperatures of the semiconductor package and the heat spreader measured after 10 minutes are 1 50.0° C. and 29.0° C., respectively. Thus, it may be noted that a desired heating temperature may be rapidly set using the test socket of the present invention.

According to the present invention, the object may be directly provided with a desired test temperature using the thermoelectric element. Thus, the desired test temperature may be set rapidly and accurately. Further, the heat transfer member interposed between the object and the thermoelectric element may quickly dissipate the heat in the object.

The foregoing is illustrative of the present invention and is not to be construed as limiting thereof. Although a few embodiments in accordance with the present invention have been described, those skilled in the art will readily appreciate that many modifications are possible in the embodiments without materially departing from the novel teachings and advantages of this invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A test socket comprising:
a socket body configured to receive an object;
a thermoelectric element placed in the socket body to emit heat and absorb heat by a current provided to the thermoelectric element; and
a heat transfer member arranged between the object and the thermoelectric element to transfer the heat in the object to the thermoelectric element.

2. The test socket of claim 1, wherein the socket body comprises:
a base configured to hold the object; and
a lid rotatably connected to the base to cover the base, the lid configured to hold the thermoelectric element and the heat transfer member.

3. The test socket of claim 2, wherein the socket body further comprises a latch rotatably connected to the lid to detachably fix the lid to the base.

4. The test socket of claim 3, wherein the socket body further comprises a locking spring configured to resiliently bias the latch toward the base.

5. The test socket of claim 4, wherein the latch has a holding protrusion selectively inserted into a holding groove that is formed at the base.

6. The test socket of claim 2, wherein the lid comprises a housing for movably receiving the heat transfer member.

7. The test socket of claim 1, further comprising a contact spring configured to resiliently bias the heat transfer member toward the object to ensure contact between the heat transfer member and the object.

8. The test socket of claim 1, further comprising a heat spreader contacting the thermoelectric element to dissipate the heat in the thermoelectric element.

9. The test socket of claim 8, wherein the heat spreader includes a plurality of protrusions that enlarge a heat dissipation area of the heat spreader.

10. The test socket of claim 1, further comprising a fan configured to suck the heat in the thermoelectric element.

11. The test socket of claim 1, wherein the object comprises a semiconductor package.

12. The test socket of claim 1, wherein the thermoelectric element comprises:
first and second heat-emitting plates configured to emit the heat;
a heat-absorbing plate electrically connected to the first and second heat-emitting plates to absorb the heat; and
N-type and P-type semiconductor devices interposed between the heat-absorbing plate and the first and second heat-emitting plates.

13. A test socket comprising:
a base configured to hold an object;
a lid rotatably connected to the base to cover the base;
a latch rotatably connected to the lid to detachably fix the lid to the base;
a locking spring configured to resiliently bias the latch toward the base;
a thermoelectric element placed in the lid to emit heat and absorb heat by a current provided to the thermoelectric element;
a heat transfer member arranged between the object and the thermoelectric element to transfer the heat in the object to the thermoelectric element;
a heat spreader making contact with the thermoelectric element to dissipate the heat in the thermoelectric element;
a contact spring installed at the heat spreader to resiliently bias the heat spreader, the thermoelectric element and the heat transfer member toward the object; and
a fan arranged over the heat spreader to suck the heat in the heat spreader.

14. The test socket of claim 13, wherein the latch includes a holding protrusion selectively inserted into a holding groove that is formed at the base.

15. The test socket of claim 13, wherein the heat spreader has a plurality of protrusions configured to enlarge a heat dissipation area of the heat spreader, and the contact spring is wound on the holding protrusions.

16. A test socket comprising:
a socket body configured to receive a semiconductor package;
a thermoelectric element placed in the socket body to emit heat and absorb heat by a current provided to the thermoelectric element; and
a heat transfer member arranged between the semiconductor package and the thermoelectric element to transfer the heat in the semiconductor package to the thermoelectric element;
a heat spreader making contact with the thermoelectric element to dissipate the heat in the thermoelectric element; and
a fan arranged over the heat spreader to suck the heat in the heat spreader.

17. The test socket of claim 16, wherein the heat spreader has a plurality of protrusions configured to enlarge a heat dissipation area of the heat spreader.

18. The test socket of claim 16, further comprising a contact spring configured to resiliently bias the heat spreader, the thermoelectric element and the heat transfer member toward the semiconductor package.
